(19) United States
(12) Patent Application Publication
(10) Pub. No.: US 2024/0209260 A1
(43) Pub. Date: Jun. 27, 2024

(54) ETCHING SOLUTION

(71) Applicant: Kao Corporation, Tokyo (JP)

(72) Inventor: Kanji SATO, Wakayama (JP)

(73) Assignee: Kao Corporation, Tokyo (JP)

(21) Appl. No.: 18/287,778

(22) PCT Filed: Apr. 22, 2022
(86) PCT No.: PCT/JP2022/018503

§ 371 Date: Oct. 20, 2023

(30) Foreign Application Priority Data
Apr. 22, 2021 (JP) 2021-072537

(51) Int. Cl. C09K 13/06; H01L 21/311

(52) U.S. Cl. CPC C09K 13/06; H01L 21/31111

(57) ABSTRACT

In one aspect, provided is an etchant that is able to reduce the deposition and adhesion of silica, which is produced in an etching process, on a silicon oxide film.

An aspect of the present disclosure relates to an etchant for a process of removing a silicon nitride film from a substrate having a silicon nitride film and a silicon oxide film. The etchant contains a siloxane compound modified with a compound having an alkyleneoxy group, a phosphoric acid, and water.

### TECHNICAL FIELD

The present disclosure relates to an etchant for a silicon nitride film, an etching method by using the etchant, and a method for producing a semiconductor substrate by using the etchant.

### BACKGROUND ART

In the manufacturing process of a semiconductor device, a substrate having a silicon nitride film (also referred to as an “SiN film” in the following) and a silicon oxide film (also referred to as an “SiO₂ film” in the following) is subjected to a process of selective etching and removal of the SiN film. A conventionally known etching method is to etch the SiN film with a phosphoric acid at a high temperature of 150° C. or more.

In the field of semiconductor, wiring has been required to be finer and more complicated due to a high level of integration in recent years. There has been proposed a method for improving the ratio of the etching rate of the SiN film to the etching rate of the SiO₂ film.

JP 2016-29717 A (Patent Document 1) proposes an etching composition that contains a first inorganic acid, at least one silane inorganic acid salt produced by reacting a second inorganic acid with a silane compound, and a solvent.

JP 2018-85513 A (Patent Document 2) proposes an etching composition that contains an inorganic acid, a siloxane compound, an ammonium compound, and a solvent.

JP 2020-96162 A (Patent Document 3) proposes an etchant that is obtained by blending an organic phosphonic acid compound, a phosphoric acid, and water.

Moreover, WO 2021/242755 A1 (Patent Document 4) proposes a polishing liquid composition in a method for selectively removing the SiN film from the combination of the SiO₂ film and the SiN film. The polishing liquid composition contains ceria-coated inorganic oxide particles, a silicone-containing compound having a substituted ethylenediamine group and at least one group selected from an ethyleneoxy group (EO) or a propyleneoxy group (PO), a nonionic organic molecule having at least two hydroxyl groups, and a solvent.

### Disclosure of the Invention

An aspect of the present disclosure relates to an etchant for a process of removing a silicon nitride film from a substrate having a silicon nitride film and a silicon oxide film. The etchant contains a siloxane compound modified with a compound having an alkyleneoxy group, a phosphoric acid, and water.

An aspect of the present disclosure relates to an etching method that includes removing a silicon nitride film from a substrate having a silicon nitride film and a silicon oxide film by using the etchant of the present disclosure.

An aspect of the present disclosure relates to a method for producing a semiconductor substrate. The method includes removing a silicon nitride film from a substrate having a silicon nitride film and a silicon oxide film by using the etchant of the present disclosure. The substrate is used for a semiconductor.

### DESCRIPTION OF THE INVENTION

In the field of semiconductor, wiring has been required to be finer and more complicated due to a high level of integration in recent years. There is also a demand that a silicon nitride film be removed more efficiently. In particular, in the manufacturing process of a three-dimensional semiconductor device such as a three-dimensional NAND flash memory, the ratio of the etching rate of the SiN film to the etching rate of the SiO₂ film needs to be further improved in terms of productivity and yield. In the conventional etching method using a phosphoric acid at a high temperature of 150° C. or more, a part of the SiN film is decomposed into a silicic acid (Si(OH)₄) and ammonium phosphate ((NH₄)PO₄), and then a part of the silicic acid undergoes dehydration to produce silica (SiO₂). This poses a problem that the silica will be deposited on and adhere to the surface of the SiO₂ film. Therefore, an etchant is particularly required that is able to reduce the deposition and adhesion of silica on the SiO₂ film, even if the concentration of the silica produced in the etching process is high (e.g., 200 ppm).

The present disclosure provides an etchant that is able to reduce the deposition and adhesion of silica, which is produced in the etching process, on a silicon oxide film, an etching method by using the etchant, and a method for producing a semiconductor substrate by using the etchant.

In one aspect, the present disclosure can provide the etchant that is able to reduce the deposition and adhesion of silica, which is produced in the etching process, on a silicon oxide film.

In one or more embodiments, the present disclosure relates to an etchant (also referred to as an “etchant of the present disclosure” in the following) for a process of removing a silicon nitride film from a substrate having a silicon nitride film and a silicon oxide film. The etchant of the present disclosure contains a siloxane compound modified with a compound having an alkyleneoxy group, a phosphoric acid, and water.

The etchant of the present disclosure can reduce the deposition and adhesion of silica, which is produced in the etching process, on the silicon oxide film.

The details of the mechanism of the effect of the present disclosure are not fully clear, but can be assumed as follows.

In the present disclosure, the siloxane compound modified with a compound having an alkyleneoxy group. e.g., the siloxane compound represented by the formula (II) is adsorbed on Si(OH)₄ or silica produced in the etching process, or on the surface of the SiO₂ film. The siloxane compound adsorbed on the surface of the SiO₂ film can act as a protective film to prevent the deposition and adhesion of silica. The siloxane compound adsorbed on silica can repel the siloxane compound that has been adsorbed on the surface of the SiO₂ film, so that the adhesion of the silica can be prevented.

However, the present disclosure should not be interpreted solely by the above mechanism.

In one or more embodiments, the etchant of the present disclosure can be prepared by blending a siloxane compound modified with a compound having an alkyleneoxy group, a phosphoric acid, and water, and optional components as needed. In other words, in one or more embodiments, a siloxane compound modified with a compound having an alkyleneoxy group, a phosphoric acid, and water are blended to form the etchant of the present disclosure.

In the context of the present disclosure, the phrase “(be) blended to form” means that optional components may be mixed as needed, in addition to the siloxane compound modified with a compound having an alkyleneoxy group, the phosphoric acid, and water. In the present disclosure, the blending amount of each component in the etchant may be read as the content of. each component in the etchant.

[Siloxane Compound Modified with Compound having Alkyleneoxy Group]

In one or more embodiments, the etchant of the present disclosure contains a siloxane compound modified with a compound having an alkyleneoxy group. In one or more embodiments, a siloxane compound modified with a compound having an alkyleneoxy group is blended in the etchant of the present disclosure. The siloxane compound modified with a compound having an alkyleneoxy group may be used alone, or two or more types of the siloxane compounds may be used in combination. The alkyleneoxy group may be, e.g., at least one selected from the group consisting of an ethyleneoxy group (EO) and a propyleneoxy group (PO), and is preferably the EO from the viewpoint of reducing the deposition and adhesion of silica on the SiO₂ film.

In the present disclosure, the siloxane compound modified with a compound having an alkyleneoxy group is preferably a siloxane compound with a structure represented by the following formula (I), and more preferably a siloxane compound represented by the following formula (II) from the viewpoint of reducing the deposition and adhesion of silica on the SiO₂ film.

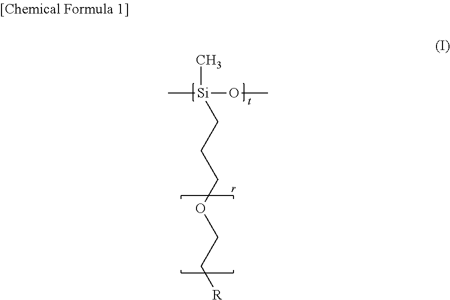

In the formula (I), R represents an alkyl group having 1 to 5 carbon atoms, a hydroxyalkyl group having 1 to 5 carbon atoms, an alkoxy group having 1 to 5 carbon atoms, or an anionic group, t represents 1 or more and 50 or less, and r represents 1 or more and 30 or less.

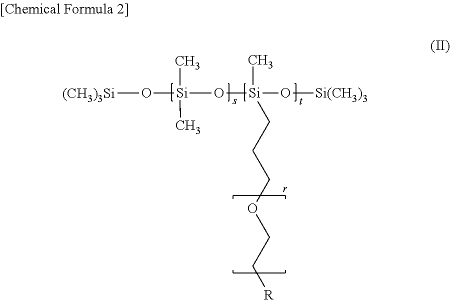

In the formula (II), R represents an alkyl group having 1 to 5 carbon atoms, a hydroxyalkyl group having 1 to 5 carbon atoms, an alkoxy group having 1 to 5 carbon atoms, or an anionic group, t/(s+t)×100 is 4 or more, and r represents 1 or more and 30 or less.

In the formulas (I) and (II), the anionic group may be, e.g. a phosphonic acid group, a sulfate group, a carboxylic acid group, or a phosphate group (—O—PO—(OH)₂).

In the formulas (I) and (II), R is preferably an alkyl group having 1 to 5 carbon atoms, an alkoxy group having 1 to 5 carbon atoms, or an anionic group, more preferably a methyl group, a methoxy group, or a phosphate group, and further preferably a phosphate group from the viewpoint of reducing the deposition and adhesion of silica on the SiO₂ film.

In the formula (II), from the viewpoint of reducing the deposition and adhesion of silica on the SiO₂ film, t/(s+t)×100 is 4 or more, preferably 7 or more, more preferably 10 or more, even more preferably 15 or more, still more preferably 20 or more, yet more preferably 30 or more, and further preferably 40 or more. Furthermore, t/(s+t)×100 is preferably 100 or less. more preferably 80 or less, even more preferably 70 or less, and further preferably 60 or less. From the same viewpoint, t/(s+t)×100 is preferably 4 or more and 100 or less, and more preferably 7 or more and 100 or less.

In the formulas (I) and (II), from the same viewpoint, t is preferably 1 or more and 50 or less, and more preferably 1 or more and 30 or less.

In the formulas (I) and (ID), ris 1 or more and 30 or less, and from the same viewpoint, r is preferably 1 or more and 25 or less, and more preferably 3 or more and 20 or less.

An HLB (hydrophile-lipophile balance) value of the siloxane compound modified with a compound having an alkyleneoxy group is preferably 4 or more, more preferably 5 or more, and further preferably 10 or more from the viewpoint of reducing the deposition and adhesion of silica on the SiO₂ film. The HLB value is defined by “7+sum total of hydrophilic group numbers−sum total of lipophilic group numbers” where the group numbers are based on functional groups, as described in Davies, J. T .; Proc. Intern. Congr. Surface Activity, 2nd, London, 1, 426 (1957).

The siloxane compound modified with a compound having an alkyleneoxy group may be, e.g., at least one selected from the group consisting of dimethicone PEG-7 phosphate (HLB: 14.6), PEG-3 dimethicone (HLB: 4.5), PEG-10 dimethicone (HLB: 4.5 or 14), and trisiloxane ethoxylate (HLB: 5.4).

The blending amount of the siloxane compound modified with a compound having an alkyleneoxy group in the etchant of the present disclosure is preferably 0.03% by mass or more, more preferably 0.04% by mass or more, and further preferably 0.05% by mass or more from the viewpoint of reducing the deposition and adhesion of silica on the SiO₂ film. From the same viewpoint, the blending amount of the siloxane compound modified with a compound having an alkyleneoxy group is preferably 0.2% by mass or less, more preferably 0.15% by mass or less, and further preferably 0.1% by mass or less. From the same viewpoint, the blending amount of the siloxane compound modified with a compound having an alkyleneoxy group is preferably 0.03% by mass or more and 0.2% by mass or less, more preferably 0.04% by mass or more and 0.15% by mass or less, and further preferably 0.05% by mass or more and 0.1% by mass or less. When the siloxane compound modified with a compound having an alkyleneoxy group is a combination of two or more types, the blending amount is the total amount of the two or more types.

The blending amount of the siloxane compound modified with a compound having an alkyleneoxy group in the etchant of the present disclosure is preferably 0.01% by mass or more, more preferably 0.02% by mass or more, and further preferably 0.03% by mass or more from the viewpoint of improving the ratio of the etching rate of the silicon nitride film to the etching rate of the silicon oxide film (SiN/SiO₂ selective etching rate ratio). From the same viewpoint, the blending amount of the siloxane compound modified with a compound having an alkyleneoxy group is preferably 0.2% by mass or less, more preferably 0.1% by mass or less, even more preferably 0.08% by mass or less, and further preferably 0.05% by mass or less. From the same viewpoint, the blending amount of the siloxane compound modified with a compound having an alkyleneoxy group is preferably 0.01% by mass or more and 0.2% by mass or less, more preferably 0.02% by mass or more and 0.1% by mass or less, even more preferably 0.03% by mass or more and 0.08% by mass or less, and further preferably 0.03% by mass or more and 0.05% by mass or less.

### [Phosphoric Acid]

The blending amount of the phosphoric acid in the etchant of the present disclosure is preferably 50% by mass or more, more preferably 70% by mass or more, and further preferably 80% by mass or more from the viewpoint of improving the ratio of the etching rate of the silicon nitride film to the etching rate of the silicon oxide film (also referred to as a “SiN/SiO₂ selective etching rate ratio” in the following). From the same viewpoint, the blending amount of the phosphoric acid is preferably 95% by mass or less, more preferably 90% by mass or less, and further preferably 85% by mass or less. From the same viewpoint, the blending amount of the phosphoric acid is preferably 50% by mass or more and 95% by mass or less, more preferably 70% by mass or more and 90% by mass or less, and further preferably 80% by mass or more and 85% by mass or less.

### [Water]

Water contained in the etchant of the present disclosure may be, e.g., distilled water, ion-exchanged water, pure water, or ultrapure water. The blending amount of the water in the etchant of the present disclosure is preferably 2% by mass or more, more preferably 5% by mass or more, and further preferably 7% by mass or more. Furthermore, the blending amount of the water is preferably 30% by mass or less, more preferably 25% by mass or less, and further preferably 20% by mass or less.

### [High Temperature Stabilizer]

In one or more embodiments, the etchant of the present disclosure may further contain or may be further blended with a high temperature stabilizer from the viewpoint of reducing filter clogging in cyclic use, while maintaining the SiN/SiO₂ selective etching rate ratio. The high temperature stabilizer may be at least one selected from the group consisting of a sulfonic acid compound, a maleic acid, and an oxalic acid. Examples of the sulfonic acid compound include a p-toluenesulfonic acid and a benzenesulfonic acid.

### [Organic Phosphonic Acid Compound]

In one or more embodiments, the etchant of the present disclosure may further contain or may be further blended with an organic phosphonic acid compound from the viewpoint of improving the SiN/SiO₂ selective etching rate ratio and/or further reducing the deposition and adhesion of silica on the SiO₂ film. Examples of the organic phosphonic acid compound include phosphoric acid-based polymers such as a polyvinyl phosphonic acid (PVPA), an alkyl phosphonicacid, an alkenyl phosphonic acid, and an alkyl ether phosphonic acid from the viewpoint of improving the SiN/SiO₂ selective etching rate ratio and reducing the deposition and adhesion of silica on the SiO₂ film.

### [Nonionic Surfactant]

In one or more embodiments, the etchant of the present disclosure may further contain or may be further blended with a nonionic surfactant from the viewpoint of further reducing the deposition and adhesion of silica on the SiO₂ film. Examples of the nonionic surfactant include polyoxyalkylene alkyl ethers from the viewpoint of reducing the deposition and adhesion of silica on the SiO₂ film. For example, the nonionic surfactant may be at least one selected from the group consisting of polyoxyethylene lauryl ether, polyoxyethylene oleyl ether, and polyoxyethylene polyoxypropylene lauryl myristyl ether.

### [Other Components]

The etchant of the present disclosure may further contain or may be further blended with other components to the extent that they do not interfere with the effects of the present disclosure. The other components include, e.g., acids other than a phosphoric acid, a chelating agent, surfactants other than the nonionic surfactants as described above, a solubilizing agent, an antiseptic, an anticorrosive, a bactericide, an antibacterial agent, and an antioxidant.

### [Production Method of Etchant]

In one aspect, the present disclosure relates to a method for producing an etchant (also referred to as a “production method of an etchant of the present disclosure” in the following). The production method of an etchant of the present disclosure includes blending a siloxane compound modified with a compound having an alkyleneoxy group, a phosphoric acid, and water, and the optional components as needed (also referred to as a “blending process” in the following).

In the context of the present disclosure, the term “blend” includes mixing the siloxane compound modified with a compound having an alkyleneoxy group, the phosphoric acid, and water, and the optional components as needed, simultaneously or in sequence. They can be mixed in any order. The blending can be performed, e.g., with a mixer such as a homomixer, a homogenizer, an ultrasonic disperser, or a wet ball mill.

From the viewpoint of improving the SiN/SiO₂ selective etching rate ratio, the pH of the etchant of the present disclosure is preferably 0.1 or more, more preferably 0.2 or more, and further preferably 0.3 or more. Furthermore, the pH of the etchant is preferably 2 or less, more preferably 1.5 or less, and further preferably 1 or less. From the same viewpoint, the pH of the etchant is preferably 0.1 or more and 2 or less, more preferably 0.2 or more and 1.5 or less, and further preferably 0.3 or more and 1 or less. In the present disclosure, the pH of the etchant is a value of the etchant in use at 25° C. and can be measured with a pH meter. Specifically, the pH of the etchant can be measured by a method as described in Examples.

In one or more embodiments, the etchant of the present disclosure is used for etching at an etching temperature of 110° ° C.or more and 250° C. or less.

The etchant of the present disclosure may be concentrated so as not to impair the stability, and stored and supplied in the concentrated state. This can reduce the production and transportation costs. If necessary, the concentrated solution may be appropriately diluted with, e.g., water or a phosphoric acid aqueous solution and used in the etching process. The dilution factor is preferably 5 to 100.

### [Kit]

In one aspect, the present disclosure relates to a kit for producing the etchant of the present disclosure (also referred to as a “kit of the present disclosure” in the following).

A kit of the present disclosure may be, e.g., a kit (two-part etchant) that includes a solution (first solution) containing a siloxane compound modified with a compound having an alkyleneoxy group and a solution (second solution) containing a phosphoric acid so that the two solutions are not mixed with each other. The first solution and the second solution may be mixed at the time of use. After the first solution and the second solution are mixed together, the mixed solution may be diluted with water or a phosphoric acid aqueous solution as needed. The first solution or the second solution may contain the whole or part of the amount of water used for the preparation of the etchant. The phosphoric acid contained in the second solution may correspond to the whole or part of the amount of the phosphoric acid used for the preparation of the etchant. Each of the first solution and the second solution may contain the above optional components as needed.

The kit of the present disclosure can provide an etchant capable of reducing the deposition and adhesion of silica, which is produced in the etching process, on the SiO₂ film.

### [Substrate to be Treated]

In one or more embodiments, a substrate to be treated (subjected to an etching treatment) with the etchant of the present disclosure is a substrate having a silicon nitride film and a silicon oxide film. In one or more embodiments, the substrate having a silicon nitride film and a silicon oxide film may be a substrate with a three-dimensional structure in which a plurality of silicon nitride films and a plurality of silicon oxide films are alternately stacked. Examples of the substrate include substrates used for semiconductors and substrates used for flat panel displays. The silicon nitride film may be formed by, e.g., a low pressure chemical vapor deposition (LPCVD) method, a plasma-enhanced chemical vapor deposition (PECVD) method, or an atomic layer deposition (ALD) method. The silicon oxide film may be formed by, e.g., a thermal oxidation method, an LPCVD method, a PECVD method, or an ALD method.

In one or more embodiments, the etchant of the present disclosure can be suitably used for the production of a three-dimensional semiconductor device such as a three-dimensional NAND flash memory. For example, in one or more embodiments, the etchant of the present disclosure can be used to etch the substrate with a three-dimensional structure in which a plurality of silicon nitride films and a plurality of silicon oxide films are alternately stacked.

### [Etching Method]

In one aspect, the present disclosure relates to an etching method (also referred to as an “etching method of the present disclosure” in the following). The etching method of the present disclosure includes removing a silicon nitride film from a substrate having a silicon nitride film and a silicon oxide film by using the etchant of the present disclosure (also referred to as an “etching process” in the following).

The etching method of the present disclosure can reduce the deposition and adhesion of silica, which is produced in the etching process, on the SiO₂ film, and thus can be effective in improving the productivity of a high-quality semiconductor substrate. The etching method and conditions in the above etching process may be the same as those in the etching process of a method for producing a semiconductor substrate of the present disclosure, as will be described below.

### [Production Method of Semiconductor Substrate]

In one aspect, the present disclosure relates to a method for producing a semiconductor substrate (also referred to as a “production method of a semiconductor substrate of the present disclosure” in the following). The production method of a semiconductor substrate of the present disclosure includes removing a silicon nitride film from a substrate having a silicon nitride film and a silicon oxide film by using the etchant of the present disclosure (i.e., an etching process). The substrate is used for a semiconductor.

The production method of a semiconductor substrate of the present disclosure can reduce the deposition and adhesion of silica, which is produced in the etching process, on the SiO₂ film, and thus can be effective in efficiently producing a high quality semiconductor substrate.

Examples of the etching treatment in the etching process include immersion etching and single wafer etching.

From the viewpoint of improving the SiN/SiO₂ selective etching rate ratio, the etching temperature of the etchant in the etching process is preferably 110° C. or more, more preferably 120° C. or more, even more preferably 140° C. or more, and further preferably 150° C. or more. Furthermore, the etching temperature of the etchant is preferably 250° C. or less, more preferably 230° C. or less. even more preferably 200° C. or less, and further preferably 180° C. or less. From the same viewpoint, the etching temperature of the etchant is preferably 110° C. or more and 250° C. or less, more preferably 120° C. or more and 230° C. or less, even more preferably 140° C. or more and 200° C. or less, and further preferably 150° C. or more and 180° C. or less.

In the etching process, the etching time may be set to, e.g., preferably 30 minutes or more, and more preferably 60 minutes or more, and may also be set to, e.g., preferably 270 minutes or less, and more preferably 180 minutes or less.

In the etching process, the etching rate of the silicon nitride film is preferably 40 Å/min or more, more preferably 50 Å/min or more, and further preferably 60 Å/min or more from the viewpoint of improving productivity.

In the etching process, the etching rate of the silicon oxide film is preferably 1 Å/min or less, more preferably 0.5 Å/min or less, and further preferably 0.3 Å/min or less from the viewpoint of improving productivity.

In the etching process, the SiN/SiO₂ selective etching rate ratio is preferably 150 or more, more preferably 200 or more, and further preferably 300 or more from the viewpoint of improving productivity.

### EXAMPLES

Hereinafter, the present disclosure will be described in detail by way of examples. However, the present disclosure is not limited to the following examples.

### 1. Preparation of Etchant (Examples 1 to 7 and Comparative Examples 1 to 4)

Etchants (pH: 0.45) of Examples 1 to 7 and Comparative Examples 1 to 4 were prepared by blending the siloxane compound represented by the formula (II) or additive and the phosphoric acid aqueous solution, and optionally water, as shown in Table 1. Table 1 shows the blending amounts (% by mass, active part) of the siloxane compound or additive, the phosphoric acid, and water in each of the etchants.

The etchants were prepared by using the following components

### Siloxane Compound Represented by Formula (II)

Dimethicone PEG-7 phosphate [“PS-100” manufactured by PHOENIX CHEMICAL, INC., HLB: 14.6]

PEG-3 dimethicone [“KF-6015” manufactured by Shin Etsu Chemical Co., Ltd., HLB: 4.5]

PEG-10 dimethicone [“KF-6017” manufactured by Shin.Etsu Chemical Co., Ltd., HLB: 4.5]

PEG-10 dimethicone [“KF-6043” manufactured by Shin-Etsu Chemical Co., Ltd., HLB: 14]

Trisiloxane ethoxylate [“SILWET L-77” manufactured by Bio Medical Science, HLB: 5.4]

### Additive

PVPA (polyvinyl phosphonic acid) [manufactured by Maruzen Petrochemical Co., Ltd.]

3-[[3-aminopropyl(dimethyl)silyl]oxy-dimethylsilyl]propan-1-amine [manufactured by FUJIFILM Wako Pure Chemical Corporation]

Dimethyldimethoxysilane [manufactured by Tokyo Chemical Industry Co., Ltd.]

### Phosphoric Acid

Phosphoric acid aqueous solution [manufactured by RIN KAGAKU KOGYO Co., Ltd., phosphoric acid concentration: 85%]

### 2. Method for Measuring Each Parameter

### [pH of Etchant]

The pH value of the etchant at 25° C. was measured with a pH meter (manufactured by DKK TOA CORPORATION). Specifically, the pH value was obtained 1 minute after the electrode of the pH meter was immersed in the etchant.

### [Calculation Method of r, s, and t of Siloxane Compound Represented by Formula (ID)]

A modification rate and the number of moles of EO added (represented by r) were calculated by H-NMR (nuclear magnetic resonance system), and an average molecular weight was measured by size exclusion chromatography (SEC). Then, sand t were calculated from the resulting values.

### <H·NMR Condition>

System: JNM-ESC400 (manufactured by JEOL Ltd.)

Number of scans: 8

Relaxation delay: 30 s

Pulse angle: 45°

### <SEC Condition>

Column: K-806L+K-806L (manufactured by Showa Denko K.K.)

Eluent: 1 mmol/L FARMIN DM20/CHCl₃

Flow rate: 1.0 mL/min

Column temperature: 40° C.

Detector: RI

Injection volume: 100 μL

Molecular weight standard: polystyrene

### 3. Evaluation of Etchant

### [Etching Rate and Selective Etching Rate Ratio]

First, colloidal silica (PL-1, manufactured by FUSO CHEMICAL CO., LTD.) was added to each of the etchants (Examples 1 to 7 and Comparative Examples 1 to 4) thus prepared with their respective compositions so that the Si concentration was 200 ppm. Then, a silicon nitride film (SiN film) wafer of 1 cm×1 cm, whose thickness was measured in advance, was immersed in each of the etchants and etched at 160° C. to 170° C. for 90 minutes. After the silicon nitride film was cooled and washed with water, the thickness of the silicon nitride film was measured again. The difference in thickness of the silicon nitride film was defined as an etching amount. An optical interference film thickness measuring device (“Random Aœ VM-100” manufactured by SCREEN Semiconductor Solutions Co., Ltd.) was used to measure the thickness of the silicon nitride film.

On the other hand, a silicone oxide film (SiO₂ film) was an LP-TEOS film of 1.5 cm×1 cm. The silicon oxide film was treated under the same conditions as the silicon nitride film, and the etching amount of the silicon oxide film was determined.

The etching rate of the silicon nitride film, the etching rate of the silicon oxide film, and the selective etching rate ratio were calculated by the following formulas. Table 1 shows the results. The effect of reducing the deposition and adhesion of silica on the silicon oxide film can be evaluated from the value of the etching rate of the silicon oxide film. If the etching rate of the silicon oxide film is a minus value, silica will be deposited on and adhere to the silicon oxide film. The closer the etching rate of the silicon oxide film to 0 Å/min, the greater the effect of reducing the deposition of silica on the silicon oxide film.

$$Etching rate ( Å / min ) of silicon nitride film ( SiN film ) = Etching amount of silicon nitride film ( Å ) / 90 ( min )$$

$$Etching rate ( Å / min ) of silicon oxide film ( {SiO}_{2} film ) = Etching amount of silicon oxide film ( Å ) / 90 ( min )$$

$$Selective etching rate ratio = etching rate of silicon nitride film / etching rate of silicon oxide film$$

TABLE 1

| | Composition | | | | | | | | | | Selective |
|---|---|---|---|---|---|---|---|---|---|---|---|
| | Phosphoric | | | | | | | | | | etching |
| | acid | Water | Siloxane compound represented by formula (II) or additive | | | | | | Etching rate | | rate |
| | Blending | Blending | | | | | | Blending | SiN | SiO₂ | ratio |
| | amount | amount | | | | t/(s + | HLB | amount | film | film | (SiN/ |
| | (mass %) | (mass %) | Type | t | s | t)*100 | value | (mass %) | Å/min | Å/min | SiO₂) |
| Ex. 1 | 83 | 16.95 | dimethicone PEG-7 phosphate | 1 | 1 | 50 | 14.6 | 0.05 | 65 | 0.04 | 1625 |
| | | | (R = phosphate group, r = 7) | | | | | | | | |
| Ex. 2 | 83 | 16.95 | dimethicone PEG-7 phosphate | 1 | 1 | 50 | 14.6 | 0.03 | 65 | 0.05 | 1300 |
| | | | (R = phosphate group, r = 7) | | | | | | | | |
| Ex. 3 | 83 | 16.95 | dimethicone PEG-7 phosphate | 1 | 1 | 50 | 14.6 | 0.1 | 65 | 0.06 | 1083 |
| | | | (R = phosphate group, r = 7) | | | | | | | | |
| Ex. 4 | 83 | 16.95 | PEG-3 dimethicone | 4 | 50 | 7 | 4.5 | 0.05 | 65 | 0.10 | 650 |
| | | | (R = methyl group, r = 3) | | | | | | | | |
| Ex. 5 | 83 | 16.95 | PEG-10 dimethicone | 5 | 117 | 4 | 4.5 | 0.05 | 65 | 0.09 | 722 |
| | | | (R = methyl group, r = 11) | | | | | | | | |
| Ex. 6 | 83 | 16.95 | PEG-10 dimethicone | 15 | 44 | 25 | 14 | 0.05 | 65 | 0.05 | 1300 |
| | | | (R = methyl group, r = 16) | | | | | | | | |
| Ex. 7 | 83 | 16.95 | trisiloxane ethoxylate | 1 | 0 | 100 | 5.4 | 0.05 | 65 | 0.07 | 929 |
| | | | (R = methoxy group, r = 1) | | | | | | | | |
| Comp. | 83 | 17 | — | | | | — | — | 65 | −8.94 | −7 |
| Ex. 1 | | | | | | | | | | | |
| Comp. | 83 | 16.95 | PVPA | | | | | 0.05 | 64 | −6.50 | −10 |
| Ex. 2 | | | | | | | | | | | |
| Comp. | 83 | 16 | 3-[[3-aminopropyl(dimethyl)silyl]oxy- | | | | | 1 | 65 | −3.87 | −17 |
| Ex. 3 | | | dimethylsilyl]propan-1-amine | | | | | | | | |
| Comp. | 83 | 16 | dimethyldimethoxysilane | | | | | 1 | 64 | −0.67 | −96 |
| Ex. 4 | | | | | | | | | | | |

As shown in Table 1, the deposition and adhesion of silica on the SiO₂ film were reduced and the SiN/SiO₂ selective etching rate ratio was improved by using the etchants of Examples 1 to 7, each of which contained the siloxane compound represented by the formula (II), as compared to the etchants of Comparative Examples 1 to 4, each of which did not contain the siloxane compound represented by the formula (II).

### Industrial Applicability

The etchant of the present disclosure is useful in a method for producing a semiconductor substrate for high density or high integration.

1. An etchant for a process of removing a silicon nitride film from a substrate having a silicon nitride film and a silicon oxide film, the etchant comprising:
a siloxane compound modified with a compound having an alkyleneoxy group;
a phosphoric acid; and
water.

2. The etchant according to claim 1, wherein a siloxane compound modified with a compound having an alkyleneoxy group, a phosphoric acid, and water are blended to form the etchant.

3. The etchant according to claim 1, wherein the siloxane compound modified with a compound having an alkyleneoxy group is a siloxane compound with a structure represented by the following formula (I): 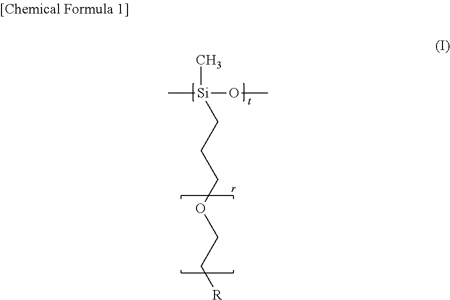
where R represents an alkyl group having 1 to 5 carbon atoms, a hydroxyalkyl group having 1 to 5 carbon atoms, an alkoxy group having 1 to 5 carbon atoms, or an anionic group, t represents 1 or more and 50 or less, and r represents 1 or more and 30 or less.

4. The etchant according to claim 1, wherein the siloxane compound modified with a compound having an alkyleneoxy group is a siloxane compound represented by the following formula (II): 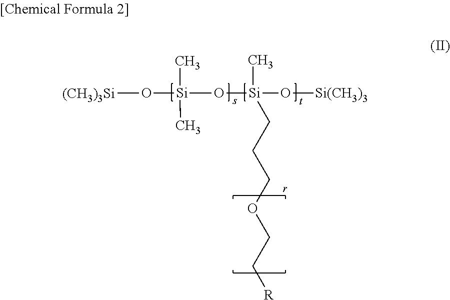
where R represents an alkyl group having 1 to 5 carbon atoms, a hydroxyalkyl group having 1 to 5 carbon atoms, an alkoxy group having 1 to 5 carbon atoms, or an anionic group, t/(s+t)×100 is 4 or more, and r represents 1 or more and 30 or less.

5. The etchant according to claim 3, wherein R in the formula (I) is a methyl group, a methoxy group, or a phosphate group.

6. The etchant according to claim 3, wherein R in the formula (I) is a phosphate group.

7. The etchant according to claim 1, having a pH of 2 or less.

8. The etchant according to claim 1, for use in etching at an etching temperature of 110° C. or more and 250° C. or less.

9. An etching method comprising:
removing a silicon nitride film from a substrate having a silicon nitride film and a silicon oxide film by using the etchant according to claim 1.

10. A method for producing a semiconductor substrate, the method comprising:
removing a silicon nitride film from a substrate having a silicon nitride film and a silicon oxide film by using the etchant according to claim 1,
wherein the substrate is used for a semiconductor.

11. The etchant according to claim 4, wherein t/(s+t)×100 is 10 or more and 80 or less in the formula (II).

12. The etchant according to claim 4, wherein R in the formula (II) is a methyl group, a methoxy group, or a phosphate group.

13. The etchant according to claim 4, wherein R in the formula (II) is a phosphate group.
